(19) United States
(12) Patent Application Publication
(10) Pub. No.: US 2022/0131051 A1
(43) Pub. Date: Apr. 28, 2022

(54) WAVELENGTH CONVERSION STRUCTURE, LIGHT-EMITTING APPARATUS AND DISPLAY DEVICE USING THE SAME

(71) Applicant: EPISTAR CORPORATION, Hsinchu (TW)

(72) Inventors: Zhen Bao, Changzhou City (CN); Wen-Tse Huang, Neihu District (TW); Ling-Xuan Hong, New Taipei City (TW); Ru-Shi Liu, New Taipei City (TW); Jia-Cheng Lin, Jiaoxi Township (TW)

(21) Appl. No.: 17/512,190

(22) Filed: Oct. 27, 2021

(30) Foreign Application Priority Data
Oct. 28, 2020 (TW) 109137359

(51) Int. Cl. H01L 33/50; H01L 33/56; G03B 21/20

(52) U.S. Cl. CPC H01L 33/504; G03B 21/204; H01L 33/56; H01L 33/507

(57) ABSTRACT

The present disclosure provides a wavelength conversion structure, a light-emitting apparatus, and a display device using the wavelength conversion structures. The wavelength conversion structure includes a porous inorganic shell and a plurality of organic complex phosphor particles filled in the porous inorganic shell. Wherein the plurality of organic complex phosphor particles is capable of being excited to emit light with a peak wavelength in the visible light range.

### RELATED APPLICATION DATA

This disclosure claims the right of priority of TW Application No. 109137359, filed on Oct. 28, 2020, and the content of which is hereby incorporated by reference in its entirety.

### TECHNICAL FIELD

The present disclosure is related to a wavelength conversion structure, a light emitting apparatus, and a display device using the wavelength conversion structures. The present disclosure is especially related to a wavelength conversion structure including a porous inorganic shell and a plurality of organic complex phosphor particles filled in the porous inorganic shell, a light emitting apparatus, and a display device using the wavelength conversion structures.

### DESCRIPTION OF BACKGROUND ART

The light emitting apparatus such as a display device, an illumination device, or a backlight module requires color mixing under many different conditions. Compared to the traditional assembly of a light source which is composed of a red light-emitting diode (LED), a green LED, and a blue LED, the light source thereof which adopts the short wavelength LEDs such as the ultraviolet (UV) LEDs and the blue LEDs along with the wavelength conversion structures to produce a white light is also extensively used based on the consideration of the cost and the efficiency.

Besides, a single-color short wavelength LED chip is sufficient to produce different color lights by combining the short wavelength LED and the wavelength conversion structure so the driving circuit thereof can be simplified. Furthermore, an array of the single-color LED arrays formed on the same substrate can be transferred simultaneously so the assembling period and the manufacturing cost thereof can be reduced and the manufacturing procedures can also be simplified.

In recent years, the wavelength conversion materials specialized for the LEDs are extensively researched and developed. However, the present wavelength conversion materials still have problems such as the asymmetric light-emitting spectrum, the large energy loss, and the low light-emitting efficiency of reduced particle sizes thereof.

### SUMMARY OF THE DISCLOSURE

The present disclosure provides a wavelength conversion structure, a light-emitting apparatus, and a display device using the wavelength conversion structures. The wavelength conversion structure includes a porous inorganic shell and a plurality of organic complex phosphor particles filled in the porous inorganic shell. Wherein the plurality of organic complex phosphor particles is capable of being excited to emit a light with a peak wavelength in the visible light range.

In another aspect, the present disclosure provides a light-emitting apparatus including an LED device and a plurality of wavelength conversion structures disposed on the LED device.

In another aspect, the present disclosure provides a display device including the wavelength conversion structures. The display device includes a backplane, and the backplane includes a plurality of pixel regions. Each pixel region can emit a red light, a green light, and a blue light and include a first LED device, a second LED device, and a wavelength conversion layer disposed on the second LED device. Wherein, the wavelength conversion layer includes the wavelength conversion structures.

### BRIEF DESCRIPTION OF THE DRAWINGS

FIG. 1 shows X-ray diffraction spectrums of standard porous inorganic shells MSN, standard (C₁₀H₁₄N)₂MnBr₄, and a wavelength conversion structure in accordance with one embodiment of the present disclosure.

FIG. 2A shows a high-resolution electron microscopy image of the porous inorganic shells in accordance with one embodiment of the present disclosure.

FIG. 2B shows a high-resolution electron microscopy image of the wavelength conversion structures in accordance with one embodiment of the present disclosure.

FIG. 3 show the dispersion images of the elements of the wavelength conversion structures measured by the energy-dispersive X-ray spectroscopy in accordance with one embodiment of the present disclosure.

FIG. 4 shows a light excitation and emission spectrum in accordance with one embodiment of the present disclosure.

FIG. 5 shows a side sectional view of a light-emitting apparatus in accordance with one embodiment of the present disclosure.

FIG. 6 shows a side sectional view of a light-emitting apparatus in accordance with another embodiment of the present disclosure.

FIG. 7 shows a top view of a display device in accordance with one embodiment of the present disclosure.

FIG. 8A shows a side sectional view of a pixel region of a display device in accordance with one embodiment of the present disclosure.

FIG. 8B shows a side sectional view of a pixel region of a display device in accordance with another embodiment of the present disclosure.

FIG. 9 shows a side sectional view of a display device in accordance with another embodiment of the present disclosure.

### DETAILED DESCRIPTION OF PREFERRED EMBODIMENTS

The embodiments of the present disclosure are illustrated in details, and are plotted in the drawings. The same or the similar parts in the drawings and the specification have the same reference numeral. In the drawings, the shape and thickness of a specific element could be shrunk or enlarged. It should be noted that the element which is not shown in the drawings or described in the following description could be the structure well-known by the person having ordinary skill in the art.

The present disclosure is related to a wavelength conversion structure which includes a porous inorganic shell and a plurality of organic complex phosphor particles filled in the porous inorganic shell. This wavelength conversion structure is appliable to a variety of light-emitting apparatus. In detail, this type of wavelength conversion structure takes advantage of the spaces in the porous inorganic shell to limit and adjust the growth of the diameters of the organic complex phosphor particles filled therein while the organic complex phosphor particles are under crystallization. Therefore, the organic complex phosphor particles include appropriate sizes so that the wavelength conversion structure is applicable to a variety of light-emitting devices, especially applicable to the miniaturized LED devices. In other words, this type of wavelength conversion structure which has small particle sizes and good energy conversion efficiency is suitable for various kinds of LEDs and light-emitting apparatus, especially suitable for the miniaturized LEDs and the display devices incorporating this miniaturized LEDs.

In one embodiment of the present disclosure, the porous inorganic shells are mesoporous silica nanoparticles (represented by MSN; refractive index is between 1.2 and 1.5). The word “mesoporous” means the diameter of the pores of the porous inorganic shell is between 2 and 50 nm. The organic complex phosphor particles are manganese-containing organic complex phosphor ((C₁₀H₁₄N)₂MnBr₄). The procedure of manufacturing the wavelength conversion structures is described below:

### 1. Synthesize Porous Inorganic Shells—Mesoporous Silica Nanoparticles (MSN)

A mixed solution is formed by mixing 280 mL deionized water (DI water), 80 mL ethanol alcohol, 5.728 g hexadecyltrimethylammonium bromide (CTAB), and 0.5 mL ammonia. The mixed solution is then stirred and heated in a 60° C.-water bath for 30 minutes. While keeping stirring the mixed solution in the 60° C.-water bath for another 2 hours, 14.6 mL of tetraethoxy silane (TEOS) droplets is slowly added in the mixed solution. The mixed solution is then cooled down to the room temperature and centrifuged to collect the precipitated solid portion. The precipitated solid portion is then cleaned by the absolute ethanol three times and dried under 80° C. for 12 hours. Finally, the solid portion is put into the high temperature oven with the oven's temperature raised to 550° C. at the rate of 5° C./min and kept for 5 hours to remove the CTAB templates such that MSN can be obtained.

2. Fill the Organic Complex Phosphor Particles into the Porous Inorganic Shells

Taking MSN as the growth templates of (C₁₀H₁₄N)₂MnBr₄. The precursor solution is formed by mixing 100 mg of MSN and (C₁₀H₁₄N)₂MnBr₄ and 3 mL DI water or methyl alcohol (MeOH). The precursor solution is stirred under room temperature for one day and centrifuged to collect the precipitated solid portion. And then, the precipitated solid portion is dried such that the wavelength conversion structures (C₁₀H₁₄N)₂MnBr₄@MSN which include porous inorganic shells and a plurality of organic complex phosphor particles filled therein are obtained.

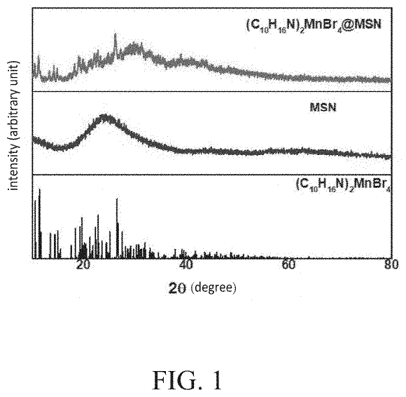

FIG. 1 shows the comparison of an X-ray diffraction spectrum of the wavelength conversion structures (C₁₀H₁₄N)₂MnBr₄@MSN in accordance with one embodiment of the present disclosure (the top diagram), an X-ray diffraction spectrum of the standard MSN structure (the middle diagram), and an X-ray diffraction spectrum of the standard (C₁₀H₁₄N)₂MnBr₄ structure (the bottom diagram). X-axis represents the diffraction angle 20 (degrees) and Y-axis represents the detected intensity (arbitrary unit). As shown in FIG. 1, the spectrum of the synthesized wavelength conversion structures (C₁₀H₁₄N)₂MnBr₄@MSN is overlapped with the spectrum of the standard MSN structure and the spectrum of the standard (C₁₀H₁₄N)₂MnBr₄ structure.

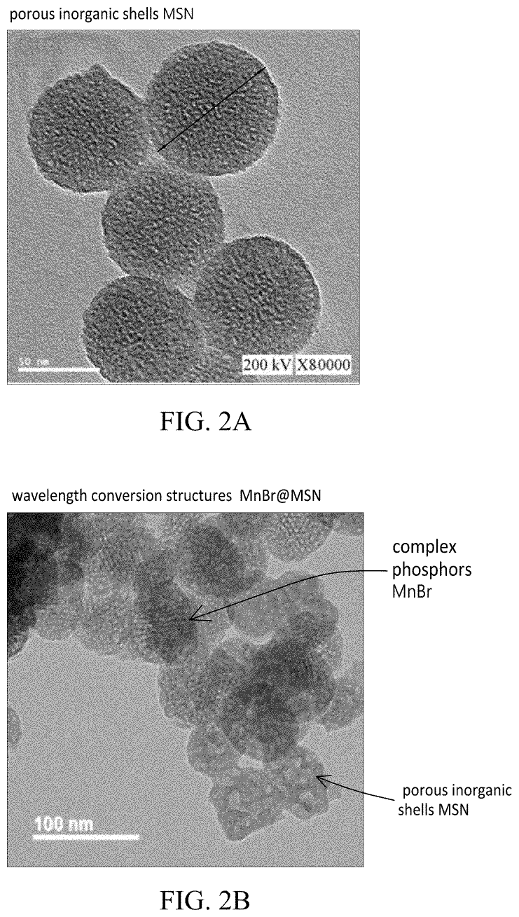

FIG. 2A shows a high-resolution electron microscopy image of MSN disclosed in one embodiment of the present disclosure and FIG. 2B shows a high-resolution electron microscopy image of (C₁₀H₁₄N)₂MnBr₄@MSN in accordance with one embodiment of the present disclosure. Observed under the transmission electron microscopy at a maximum accelerating voltage of 200 kV, the appearance of MSN are ball shapes. As shown in FIG. 2A, the sizes of MSN are similar, and the average diameters thereof are about 70 nanometers (nm). As shown in FIG. 2B, (C₁₀H₁₄N)₂MnBr₄ is in the form of black particles in the image and the black particles have the average diameter of about 2˜3 nm.

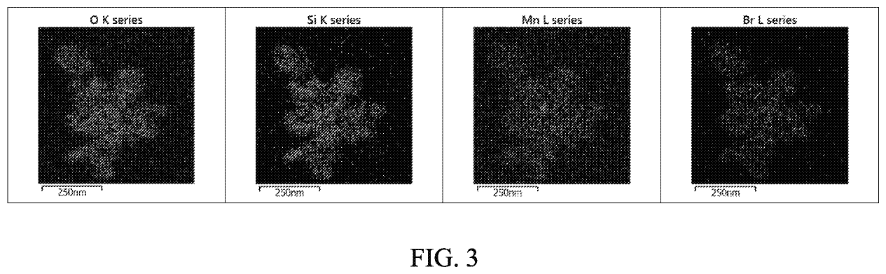

FIG. 3 shows the dispersion images of the elements of the wavelength conversion structures (C₁₀H₁₄N)₂MnBr₄@MSN measured by the energy-dispersive X-ray spectroscopy in accordance with one embodiment of the present disclosure. According to the images, the elements oxygen (O), silicon (Si), Bromine (Br), and Manganese (Mn) are uniformly dispersed in the wavelength conversion structures (C₁₀H₁₄N)₂MnBr₄@MSN.

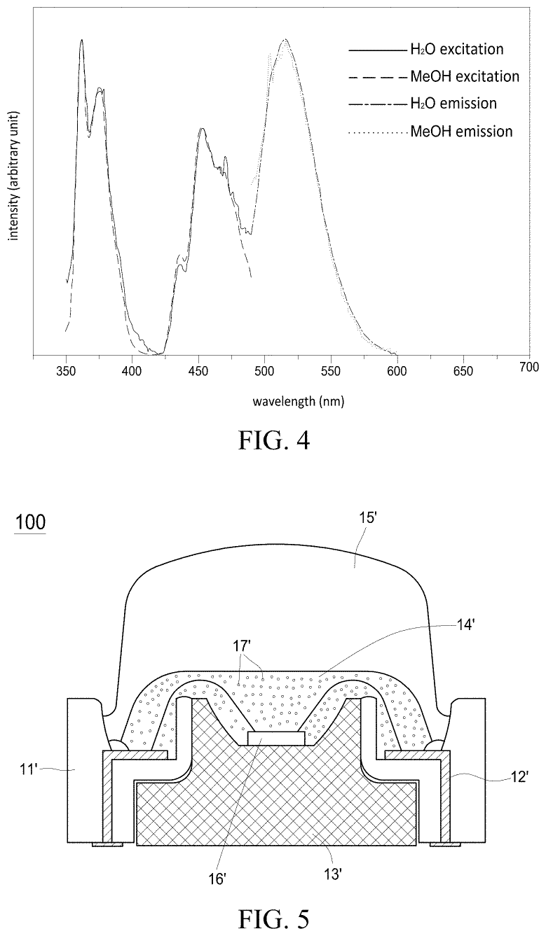

FIG. 4 shows a light excitation and emission spectrum of the wavelength conversion structures (C₁₀H₁₄N)₂MnBr₄@MSN dissolved in the water and in MeOH respectively. The horizontal axis represents the wavelength (nm) and the vertical axis represents the intensity (arbitrary unit). As shown in the spectrum, the light-emitting portions of the wavelength conversion structures (C₁₀H₁₄N)₂MnBr₄@MSN are (C₁₀H₁₄N)₂MnBr₄. (C₁₀H₁₄N)₂MnBr₄ can be excited by a 460 nm blue light and emit a light with the peak wavelength in the green light range. The emission spectrum of the wavelength conversion structures (C₁₀H₁₄N)₂MnBr₄@MSN is similar with the emission spectrum of (C₁₀H₁₄N)₂MnBr₄.

As shown in the figure, the wavelength conversion structures (C₁₀H₁₄N)₂MnBr₄@MSN can be excited by the light with a wavelength from the UV light range to the visible light range (350 nm-500 nm). The exciting peak wavelengths of the UV light and the visible light are 360 nm and 452 nm, and are corresponding to the energy state transitions ⁶A₁→⁴T₂(D) and ⁶A₁→⁴T₂(G). Therefore, a 350˜500 nm exciting light source can irradiate the wavelength conversion structures (C₁₀H₁₄N)₂MnBr₄@MSN to obtain a corresponding emission spectrum with an emission light in the visible green light region (470˜600 nm). The peak wavelength thereof is about 515 nm and corresponding to the energy state transition ⁴T₁→⁶A₁.

When using the absolute quantum yield spectrometer (for example, a model from Hamamatsu Photonics K.K.) to measure the absolute quantum yield of the synthesized wavelength conversion structures (C₁₀H₁₄N)₂MnBr₄@MSN, the absolute quantum yield thereof is larger than 37%. Furthermore, according to the analyzing results shown in the previous sections, it can be realized that the light emission characteristics of the wavelength conversion structures (C₁₀H₁₄N)₂MnBr₄@MSN are mainly determined by the properties of (C₁₀H₁₄N)₂MnBr₄.

In the embodiment, MSN is a type of porous inorganic shells and is composed of silicon dioxide (SiO₂) and the refractive index thereof is between 1.2 and 1.5. In another embodiment, another type of porous inorganic shells which are composed of aluminum oxide (Al₂O₃) can be synthesized by an evaporation-induced self-assembling method that mixing the precursor aluminium isopropoxide (AIP), the template Pluronic P123, and the swelling agent 1.3.5-triisopropylbenzene (TIPB). The refractive index thereof is between 1.65 and 1.78. In another embodiment, another type of porous inorganic shells composed of zirconia (ZrO₂) can be synthesized by a template method that mixing the layered porous templates SiO₂ and the acidic zirconia solution, removing the templates by the high temperature calcination treatment, and immersing zirconia into a basic solution to form the porous structure. The refractive index thereof is between 2.18 and 2.21. In another embodiment, another type of porous inorganic shells composed of titanium dioxide (TiO₂) can be synthesized by mixing the precursor titanium isopropoxide Ti₄(OCH₃)₁₆ and acetic acid (CH₃COOH) in absolute ethanol, slowly adding the mixed solution droplets into DI water, centrifuging the mixed solution to collect the precipitated solid portion, and the porous inorganic shells composed of titanium dioxide are formed by calcining precipitated solid portion in a high temperature. The refractive index thereof is between 2.40 and 2.76.

The average diameters of the porous inorganic shells and the average sizes of the pores in the porous inorganic shells can be adjusted by controlling the operating factors such as the synthesizing time, the PH value, and the types of the precursors in the synthesizing procedure and are not limited by the previous mentioned embodiments. The sizes of the filled organic complex phosphor particles can therefore be controlled. The appearance of the porous inorganic shells can be ball shapes, sheets, or pillars. Under normal condition, the diameters of the porous inorganic shells are smaller than 500 nm.

In the embodiment, the composition of the manganese-containing organic complex phosphor is (C₁₀H₁₆N)₂MnBr₄ and (C₁₀H₁₆N)₂MnBr₄ has a peak wavelength at 550 nm. In another embodiment, by adding one type of the aforementioned porous inorganic shells into a selected solution, the complex phosphor KSF (K₂SiF₆:Mn⁴⁺) can be filled into the pores of the porous inorganic shells to form the wavelength conversion structures which have a peak wavelength at 630 nm. In another embodiment, by mixing one type of the aforementioned porous inorganic shells and the precursors of the complex phosphor CASN ((Sr,Ca)AlSiN₃:Eu²⁺) through the gas pressure sintering reaction, the complex phosphor CASN can be filled into the pores of the porous inorganic shells to form the wavelength conversion structures which have a peak wavelength at 650 nm. In another embodiment, by mixing one type of the aforementioned porous inorganic shells and the precursors of the complex phosphor SLA (SrLiAl₃N₄:Eu²⁺) through the hot isostatic pressing reaction, the complex phosphor SLA can be filled into the pores of the porous inorganic shells to form the wavelength conversion structures which have a peak wavelength at 650 nm. According to the aforementioned embodiments, the complex phosphors which can be used to synthesize the wavelength conversion structures have the peak wavelengths in the visible light range between 550 and 650 nm.

In other words, by changing the operating factors such as the synthesizing method and the materials of the porous inorganic shells, different complex phosphor can be selected to be the components of the wavelength conversion structures. The complex phosphor can be a halide, an oxide, a nitride, an oxynitride, or a sulfide. Similarly, in the embodiment, the emission visible light of the wavelength conversion structures (C₁₀H₁₆N)₂MnBr₄@MSN is in the range between 470 and 600 nm. Because the emission wavelength is mainly determined by the complex phosphor in the wavelength conversion structures, in different embodiments, the emission wavelength of the wavelength conversion structure is changed by changing the composition of the complex phosphor in the wavelength conversion structures.

FIG. 5 shows a side sectional view of a light-emitting apparatus 100 in accordance with one embodiment of the present disclosure. The light-emitting apparatus 100 includes an insulating body 11′, a lead frame 12′, a heat sink 13′, a colloidal encapsulation 14′, a lens 15′, and a light-emitting diode element 16′. As shown in FIG. 5, in order to emit a white light, one type of the aforementioned wavelength conversion structures 17′ is mixed into the colloidal encapsulation 14′ and disposed on the light-emitting diode element 16′. According to this arrangement, by empowering the light-emitting diode element 16′ to emit a short wavelength light, for example, a UV light or a blue light, the wavelength conversion structures 17′ are excited to emit a long wavelength light so the remaining short wavelength light and the long wavelength light are mixed to form a white light.

In the embodiment, the wavelength conversion structures 17′ can be one type of the aforementioned wavelength conversion structures and are dispersed in the colloidal encapsulation 14′. The colloidal encapsulation 14′ can be a translucent material composed of an organic polymer such as polymerized siloxanes or polyepoxide. The refractive index of polymerized siloxanes is about 1.6, and the refractive index of polyepoxide is between 1.3 and 1.5. The refractive indices are similar with that of the wavelength conversion structures 17′ and between that of the light-emitting diode element 16′ and that of the environmental air. For example, the refractive index of a blue light-emitting diode chip is about 2.4 and the refractive index of air is 1. Therefore, the internal total reflection of the light-emitting apparatus 100 can be reduced and the external light extraction efficiency thereof can be enhanced.

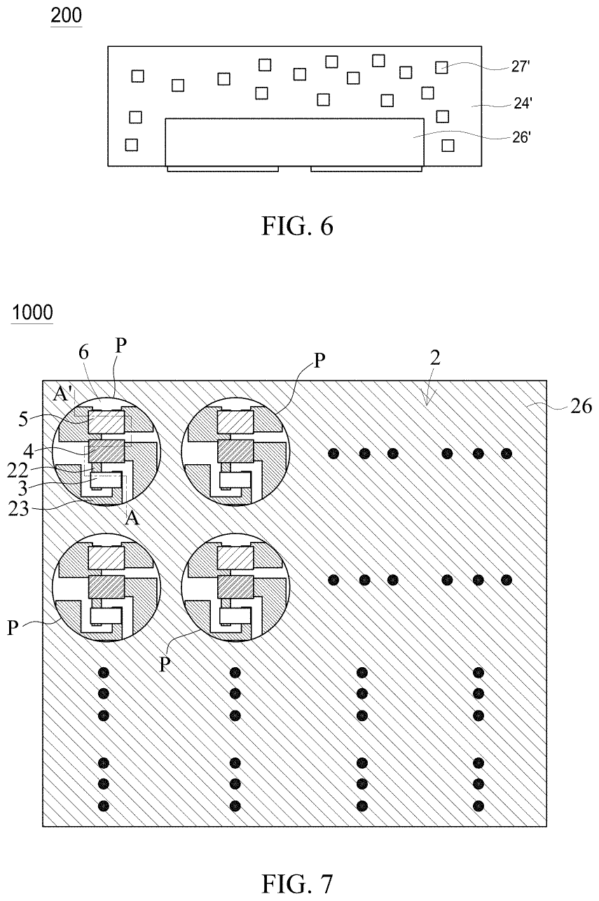

FIG. 6 shows a side sectional view of a light-emitting apparatus 200 in accordance with another embodiment of the present disclosure. After mixing one type of the aforementioned wavelength conversion structures 27′ into a translucent matrix to form a translucent colloidal encapsulation 24′, the translucent colloidal encapsulation 24′ can be disposed on a top surface, or some or all external surfaces except for the bottom surface of the light-emitting diode element 26′ as shown in the present embodiment through the method such as the spin-coating method, the spraying method, the dispensing method, and the molding method such that a chip scale packaged (CSP) light-emitting apparatus 200 is formed.

In another embodiment, because the sizes of the wavelength conversion structures are nanometer scaled, the wavelength conversion structures are small enough to be directly disposed into the light-emitting diode elements. While making the light-emitting diode elements, the epitaxial substrates or the buffer layer such as the gallium nitride (GaN) layer of the light-emitting diode elements can be etched to be porous by an etchant such as the oxalic acid. And then, spin coating the aforementioned wavelength conversion structures which are dispersed in an adequate solvent such as toluene (C₆H₆) onto the aforementioned porous structures. When this kind of light-emitting diode elements comprising the wavelength conversion structures are disposed into a light-emitting apparatus, the light-emitting apparatus also has a light-mixing effect.

FIG. 7 shows a top view of a display device 1000 in accordance with one embodiment of the present disclosure. The display device 1000 includes a plurality of pixel regions P.

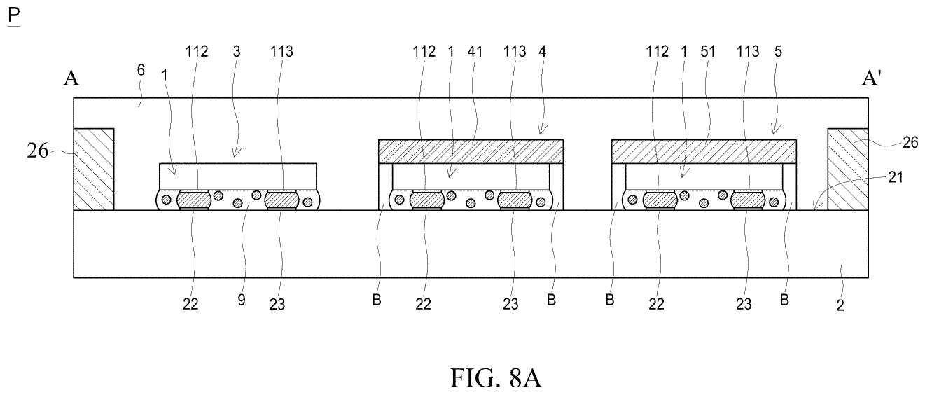

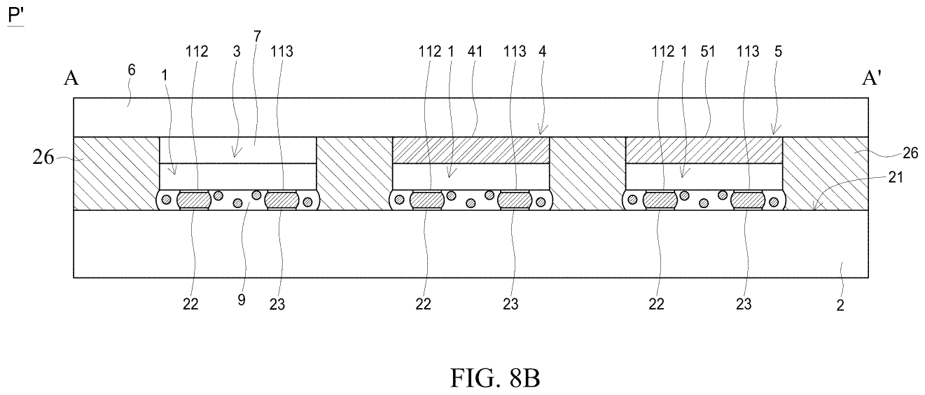

FIG. 8A shows a side sectional view of a pixel region P along line AA′ which is shown in FIG. 7 in the display device 1000. Referring to FIG. 8A, the pixel region P includes a common carrier 2, a first light-emitting diode element 3, a second light-emitting diode element 4, a third light-emitting diode element 5, and a block wall 26. In the embodiment, the first light-emitting diode element 3 includes a light-emitting diode chip 1, the block wall 26 is protruded from surface 21 of the common carrier 2 and can shield, reflect, and/or absorb the light. The block wall 26 surrounds the first light-emitting diode element 3, the second light-emitting diode element 4, and the third light-emitting diode element 5. Three pairs of a first contact pad 22 and a second contact pad 23 are disposed on the surface 21 of the common carrier 2, wherein a first electrode 112 and a second electrode 113 of the first light-emitting diode element 3 are correspondingly bonding to one pair of the first contact pad 22 and the second contact pad 23 disposed on the surface 21 of the common carrier 2. The second light-emitting diode element 4 and the third light-emitting diode element 5 are also disposed on the surface 21 of the common carrier 2. The first electrodes 112 and second electrodes 113 of the second light-emitting diode element 4 and the third light-emitting diode element 5 are respectively bonding to the corresponding two pairs of the first contact pad 22 and the second contact pad 23. The second light-emitting diode element 4 is composed of a light-emitting diode chip 1 and a first wavelength conversion layer 41 which is formed on a top surface of the light-emitting diode chip 1, and the third light-emitting diode element 5 is composed of a light-emitting diode chip 1 and a second wavelength conversion layer 51 which is formed on a top surface of the light-emitting diode chip 1. The pixel region P can optionally include a block wall B respectively surrounding the second light-emitting diode element 4 and the third light-emitting diode element 5. In particular, the block wall B surrounds each sidewall of the second light-emitting diode element 4 and the third light-emitting diode element 5 such that the unexpected color of the light which is generated from the leaked light emitting from the sidewall of the second light-emitting diode element 4 to excite the adjacent second wavelength conversion layer 51 or the leaked light emitting from the sidewall of the third light-emitting diode element 5 to excite the adjacent first wavelength conversion layer 41 can be avoided.

Further referring to FIGS. 7 and 8A, the pixel regions P are divided by a block wall 26. By using different materials and/or structures, the block wall 26 can shield, reflect, and/or absorb the light. Therefore, the crosstalk effect between the adjacent pixel regions P can be avoided. From the top view, the shape of the pixel region P formed by the block wall 26 is a circle. The shape can be adjusted to be such as a square and a rectangle according to the display requirement. The application of the display device can be a TV screen, a mobile device screen, an indoor signage, and an outdoor signage. The display device 1000 is constituted by a pixel array unit composed of a plurality of pixel regions P.

The visual perception of the observer is affected by such as the numbers, the color, the arrangement of the light-emitting diode chips in the pixel regions P, and the distance between the adjacent pixel regions P. For example, when the numbers of the pixel regions P per unit area is larger, the resolution of the display device 1000 is higher. Besides, reducing the sizes of the pixel regions P (reducing the projected areas of the pixel regions P on the common carrier 2) and the distance between the adjacent pixel regions P can also improve the resolution of the display device 1000. In the embodiment, the opening surrounded by the block wall 26 and the surface 21 of the common carrier 2 is filled with a first transparent colloid 6 to protect the light-emitting diode elements 3, 4, 5. The material of the first transparent colloid 6 includes but is not limited to polyepoxide, acrylic, silicone, or the combination thereof.

FIG. 8B shows a side sectional view of a pixel region P′ of a display device along line AA′ in accordance with another embodiment of the present disclosure. The difference between the pixel region P and the pixel region P′ is that in order to further reduce the crosstalk between the light-emitting diode elements 3, 4, 5, the block wall 26 surrounds and directly contacts the sidewalls of the light-emitting diode elements 3, 4, 5. The block wall 26 such as a light-absorbable dark colloid is composed of polyepoxide, acrylic, silicone, or the combination thereof with dye particles or carbon black particles mixed therein, and the transparency of the block wall 26 is determined by the concentration of the dye particles or carbon black particles. To simplify the manufacturing procedures of the block wall 26, a second transparent colloid 7 can be disposed on the top surface of the light-emitting diode element 3 through the method such as the spin-coating method, the spraying method, the dispensing method, and the molding method such that each of the light-emitting diode elements 3, 4, 5 includes a top surface and the top surfaces have the same height. And then, the first transparent colloid 6 are formed on the top surfaces of the second transparent colloid 7, of the light-emitting diode elements 4, 5 and of the block wall 26.

Besides the flip-chip bonding as aforementioned, in another embodiment, the face-up light-emitting diode elements are electrically connected to the contact pads through the wire-bonding method. To be more specific, “face-up” here means the electrodes of the light-emitting diode elements are away from the common carrier 2; “the wire-bonding method” here means the electrodes of the light-emitting diode element are electrically connected to the contact pads through the bridged metal wires). When the current passes through the common carrier 2 and the light-emitting diode elements 3, 4, 5, the light-emitting diode elements 3, 4, 5 respectively emit a first light, a second light, and a third light, and the first light, the second light, and the third light are capable of independently or commonly emitting a variety color of light, including a white light. For example, the first light, the second light, and the third light respectively represent the blue light, the green light, and the red light.

As shown in FIGS. 8A and 8B, the second light-emitting diode element 4 includes a light-emitting diode chip 1 which emits a first light and a first wavelength conversion layer 41 which includes one type of the aforementioned wavelength conversion structures formed on a corresponding light-emitting surface of the light-emitting diode chip 1, and the third light-emitting diode element 5 includes a light-emitting diode chip 1 which emits a first light and a second wavelength conversion layer 51 which includes one type of the aforementioned wavelength conversion structures formed on a corresponding light-emitting surface of the light-emitting diode chip 1. The light-emitting diode elements 3, 4, 5 are connected to the common carrier 2 by the conductive glues 9. In one embodiment, the light-emitting diode elements 3, 4, 5 do not include the growth substrates, which means the light-emitting diode chips 1 in the light-emitting diode elements 3, 4, 5 only include epitaxial structures, and are connected to the common carrier 2 in the flipped form (flip-chip bonding).

In one embodiment, the first light emitted by the first light-emitting diode element 3 is a blue light; the first wavelength conversion layer 41 of the second light-emitting diode element 4 includes the aforementioned wavelength conversion structures such as (C₁H₁₄N)₂MnBr₄@MSN which can emit a green light after being excited by a blue light. The green wavelength conversion structures can also be composed of the commercially available green phosphors such as β-Sialon, and orthosilicate and the aforementioned exemplified porous inorganic shells such as MSN, Al₂O₃ shells, ZrO₂ shells, and TiO₂ shells. The second light is a green light. The second wavelength conversion layer 51 of the third light-emitting diode element 5 includes aforementioned red wavelength conversion structures which can emit a red light after being excited by a blue light. The red wavelength conversion structures can be composed of the commercially available red phosphors such as KSF, CASN, and SLA and the aforementioned exemplified porous inorganic shells such as MSN, Al₂O₃ shells, ZrO₂ shells, and TiO₂ shells. The third light is a red light.

In addition, in another embodiment, the second light-emitting diode element 4 is composed of a light-emitting diode chip which emits different color from the light emitted by the light-emitting diode chip 1 and the first wavelength conversion layer 41, and the third light-emitting diode element 5 is composed of a light-emitting diode chip which emits different color from the light emitted by the light-emitting diode chip 1 and the second wavelength conversion layer 51, respectively. For example, the light-emitting diode chip 1 emits a blue light, the second light-emitting diode element 4 is composed of a UV light-emitting diode chip (light emitting wavelength between 250 and 420 nm) and the first wavelength conversion layer 41, and the third light-emitting diode element 5 is composed of a UV light-emitting diode chip and the second wavelength conversion layer 51. In general, the light-emitting diode elements 3, 4, 5 can independently or commonly emit a first light, a second light, and/or a third light.

In one embodiment, in FIG. 7, when only one pixel region P or P′ is disposed on the common carrier 2, the display device 1000 is equivalent to a pixel package X which includes a first light-emitting diode element 3, a second light-emitting diode element 4, and a third light-emitting diode element 5 which can emit a first light, a second light, and a third light, respectively. A display panel can be formed by disposing a plurality of the pixel packages X onto a backplane. In another embodiment, the pixel package X can also be composed of a plurality of pixel regions P or P′. For example, the pixel package X is composed of 2n sets of pixel regions P or P′, and n is a positive integer which is smaller than 100. The display panel can be formed by arranging a plurality of the pixel packages X in a matrix form. The numbers of the rows and the columns of the matrix can be the same or different. In a preferred embodiment, the numbers of the rows and the columns are corresponding to the aspect ratio of the display panel, such as 1:1, 4:3, and 16:8.

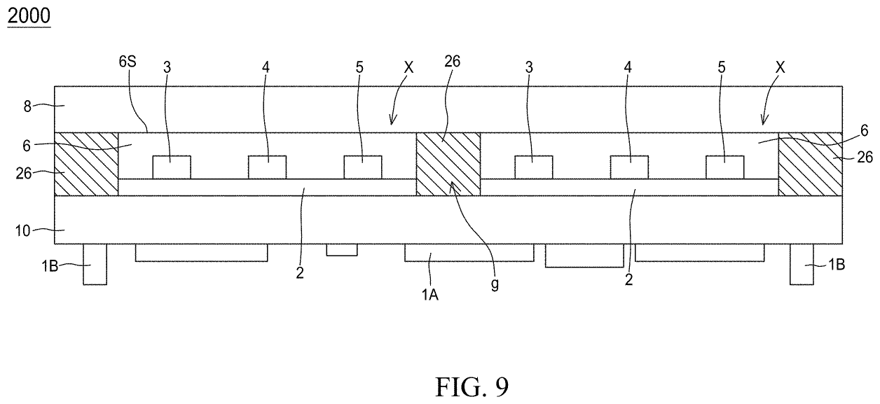

FIG. 9 shows a side sectional view of a display device 2000 in accordance with another embodiment of the present disclosure. The pixel regions in the display device 2000 are composed of the aforementioned pixel packages X. In the figure, the pixel package X is composed of one pixel region P or P′, and some details are omitted. The display device 2000 further includes a base 10 which includes a circuit (not shown), and the base 10 can be a print circuit board (PCB), a flexible printed circuit (FPC), and a glass circuit board. A plurality of the aforementioned pixel packages X are disposed on a top surface of the base 10 and electrically connected to the circuit of the base. A gap g is formed between the adjacent pixel packages X to expose the top surface of the base 10. The peripheral areas and the gaps g between the adjacent pixel packages X are filled with black or dark block walls 26. The block walls 26 are flush with, a little higher, or a little lower than the upmost surfaces 6S of the first transparent colloids 6. When the block walls 26 are opaque, the light emitted by the first light-emitting diode element 3, the second light-emitting diode element 4, and the third light-emitting diode element 5 cannot pass through the block walls 26 and is not leaked to the adjacent pixel packages X so the crosstalk effect between the adjacent pixel packages X can be avoided and the display contrast of the display device 2000 can be enhanced. A translucent protective layer 8 covers all the pixel packages X and the gaps g such that the damages caused by the external humidity or the collision can be avoided. Other optical structures such as the anti-reflective layer, the polarizer, the anti-glare layer, and the (dual) brightness enhancement film (BEF;DBEF) can also be combined into the translucent protective layer 8.

A plurality of electronic elements 1A such as the display controller, the capacitor, and the resistor are disposed under the bottom surface of the base 10 and electrically connected to the circuit of the base 10. The light-emitting mode of the pixel packages X can be feedback controlled by receiving the signals of the electronic elements 1A from the circuit of the base 10. Besides, a plurality of positioning pillars 1B can be optionally disposed under the bottom surface of the base 10 such that the display device 2000 can be arranged to a selected position and/or component thereby.

In more details, the material of the translucent protective layer 8 includes a transparent organic material such as silicone, epoxy, and the mixture thereof. It is preferred that the hardness of the translucent protective layer 8 is larger than that of the first transparent colloids 6 in order to protect the pixel packaged from collision. In one embodiment, the top surface of the translucent protective layer 8 is a flat surface. In another embodiment, by adjusting the composition of the translucent protective layer 8 or adding an anti-reflective layer on the top surface of the translucent protective layer 8, the external light reflected by the top surface of the translucent protective layer 8 can be reduced and the reflected glare which may affect the human eyes from the display device 2000 can therefore be reduced.

In another embodiment, while manufacturing the block walls 26, according to the surface tension of the block wall 26, the surfaces of the block walls 26 are in the concave form (not shown). In another embodiment, a reflective layer (not shown) is formed between the block walls 26 and the pixel packages X to reflect the light emitted by the first light-emitting diode element 3, the second light-emitting diode element 4, and the third light-emitting diode element 5.

Although the present disclosure has been explained above, it is not the limitation of the range, the sequence in practice, the material in practice, or the method in practice. Any modification or decoration for present disclosure is not detached from the spirit and the range of such.

What is claimed is:

1. A wavelength conversion structure, comprising:
a porous inorganic shell; and
a plurality of organic complex phosphor particles filled in the porous inorganic shell;
wherein the plurality of organic complex phosphor particles is capable of being excited to emit a light with a peak wavelength in the visible light range.

2. The wavelength conversion structure according to claim 1, wherein the porous inorganic shell comprises a refractive index between 1.2 and 1.5.

3. The wavelength conversion structure according to claim 1, wherein the material of the porous inorganic shell is silicon dioxide (SiO₂), aluminum oxide (Al₂O₃), zirconium dioxide (ZrO₂), or titanium dioxide (TiO₂).

4. The wavelength conversion structure according to claim 1, wherein the appearance of the porous inorganic shell is a ball shape, a sheet, or a pillar.

5. The wavelength conversion structure according to claim 1, wherein the plurality of organic complex phosphor particles is a halide, an oxide, a nitride, an oxynitride, or a sulfide.

6. The wavelength conversion structure according to claim 1, wherein the wavelength conversion structure is excited to emit a visible light in the range between 470 and 600 nm.

7. The wavelength conversion structure according to claim 1, wherein the wavelength conversion structure is excited to emit a visible light in the range between 550 and 650 nm.

8. The wavelength conversion structure according to claim 1, wherein the diameter of the porous inorganic shell is smaller than 500 nm.

9. The wavelength conversion structure according to claim 1, wherein the plurality of organic complex phosphor particles is a manganese-containing organic complex phosphor.

10. The wavelength conversion structure according to claim 1, wherein the plurality of organic complex phosphor particles is (C₁₀H₁₄N)₂MnBr₄.

11. The wavelength conversion structure according to claim 1, wherein the porous inorganic shell is a silica nanoparticle.

12. The wavelength conversion structure according to claim 1, wherein the plurality of organic complex phosphor particles is the light-emitting portion.

13. The wavelength conversion structure according to claim 1 further comprises an absolute quantum yield larger than 37%.

14. The wavelength conversion structure according to claim 1, wherein the porous inorganic shell comprises a plurality of pores with the diameters between 2 and 50 nm.

15. A light-emitting apparatus, comprising:
an LED element; and
a plurality of wavelength conversion structures as claimed in claim 1 is disposed on the LED element.

16. The light-emitting apparatus according to claim 15, the LED element further comprises a porous epitaxial substrate, and the plurality of wavelength conversion structures is formed onto the porous epitaxial substrate.

17. The light-emitting apparatus according to claim 15, the LED element further comprises a porous buffer layer, and the plurality of wavelength conversion structures is formed onto the porous buffer layer.

18. A display device, comprising:
a backplane comprising a plurality of pixel regions, and each of the plurality of pixel regions comprising a first LED element, a second LED element, and a wavelength conversion layer disposed on the second LED element;
wherein each of the plurality of pixel regions is capable of emitting a red light, a green light, and a blue light; and
wherein the wavelength conversion layer comprises the wavelength conversion structures as claimed in claim 1.

19. The display device according to claim 18, the second LED element further comprises a porous epitaxial substrate, and the plurality of wavelength conversion structures is formed onto the porous epitaxial substrate.

20. The display device according to claim 18, the second LED element further comprises a porous buffer layer, and the plurality of wavelength conversion structures is formed onto the porous buffer layer.
